(19) United States
(12) Patent Application Publication
(10) Pub. No.: US 2018/0183388 A1
(43) Pub. Date: Jun. 28, 2018

(54) N-WAY STAR CONFIGURATION POWER AMPLIFIER WITH PEAKING AMPLIFIER IMPEDANCE INVERTERS

(71) Applicant: MACOM Technology Solutions Holdings, Inc., Lowell, MA (US)

(72) Inventor: Bi Ngoc Pham, Attleboro, MA (US)

(73) Assignee: MACOM Technology Solutions Holdings, Inc., Lowell, MA (US)

(21) Appl. No.: 15/852,595

(22) Filed: Dec. 22, 2017

Related U.S. Application Data
(60) Provisional application No. 62/438,774, filed on Dec. 23, 2016.

(51) Int. Cl. H03F 1/02; H03F 1/56; H03F 3/62; H03F 3/195

(52) U.S. Cl. CPC H03F 1/0288; H03F 1/56; H03F 2200/451; H03F 3/195; H03F 2200/387; H03F 3/62

(57) ABSTRACT

Multi-way amplifiers having impedance inverters connected to outputs of one or more peaking amplifiers are described. The output of the main amplifier may connect directly to a combining node and output impedance matching network. The multi-way amplifier configuration can improve efficiency at power back-off and improve RF bandwidth.

### CROSS-REFERENCE TO RELATED APPLICATION

This Application claims priority under 35 U.S.C. § 119(e) to U.S. Provisional Application Ser. No. 62/438,774, entitled “N-WAY STAR CONFIGURATION DOHERTY POWER AMPLIFIER WITH PEAKING AMPLIFIER IMPEDANCE INVERTERS”, filed on Dec. 23, 2016, which is incorporated herein by reference in its entirety.

### BACKGROUND

### Technical Field

The technology relates to multi-way amplifiers.

### Discussion of the Related Art

High-speed power amplifiers formed from semiconductor materials have a variety of useful applications, such as radio-frequency (RF) communications, radar, RF energy, and microwave applications. Gallium nitride semiconductor material has received appreciable attention in recent years because of its desirable electronic and electro-optical properties. GaN has a wide, direct bandgap of about 3.4 eV that corresponds to the blue wavelength region of the visible spectrum. Because of its wide bandgap, GaN is more resistant to avalanche breakdown and can maintain electrical performance at higher temperatures than other semiconductors, such as silicon. GaN also has a higher carrier saturation velocity compared to silicon. Additionally, GaN has a Wurtzite crystal structure, is a very stable and hard material, has a high thermal conductivity, and has a much higher melting point than other conventional semiconductors such as silicon, germanium, and gallium arsenide. Accordingly, GaN is useful for high-speed, high-voltage, and high-power applications.

Applications supporting mobile communications and wireless internet access under current and proposed communication standards, such as WiMax, 4G, and 5G, can place austere performance demands on high-speed amplifiers constructed from semiconductor transistors. The amplifiers may need to meet performance specifications related to output power, signal linearity, signal gain, bandwidth, and efficiency. In some cases, conventional Doherty amplifiers may not be able to satisfy performance requirements for proposed communication standards.

### SUMMARY

Methods and structures for improved efficiency N-way amplifiers are described. An N-way amplifier (which may also be referred to as a multi-way amplifier) can comprise at least two amplifiers arranged to amplify, in parallel, at least two signals derived from an input signal to the N-way amplifier. By amplifying portions of a received signal in parallel, high power outputs can be obtained with a multi-way amplifier. According to some embodiments, impedance inverters are added to the output(s) of one or more peaking amplifiers that are arranged in parallel with a main amplifier. The impedance inverters can be engineered to present a desired impedance to the peaking amplifier(s) at full power operation of a multi-way amplifier. The desired impedance can be an impedance that matches a low-impedance value at an output of the main amplifier. When the peaking amplifiers are in a power back-off state, a higher impedance is presented to the main amplifier, which can improve output power back-off efficiency to values greater than 60%. A multi-way amplifier configuration having impedance inverters connected to outputs of the peaking amplifier(s) can enable broadband, high-power amplification. Additionally, the characteristic impedance of the inverters can be changed to accommodate one or more additional peaking amplifiers for higher-order multi-way amplifiers.

Some embodiments relate to an amplifier circuit comprising a power splitter; a main amplifier in a first circuit branch coupled to a first port of the power splitter and connected directly to a combining node, wherein the main amplifier is configured to continuously amplify a first portion of an input signal to the amplifier circuit when the amplifier circuit is operating; a first peaking amplifier in a second circuit branch coupled to a second port of the power splitter, wherein the first peaking amplifier is configured to intermittently amplify a second portion of the input signal when the amplifier circuit is operating; a first impedance inverter connected between an output port from the first peaking amplifier and the combining node; a second peaking amplifier in a third circuit branch coupled to a third port of the power splitter, wherein the second peaking amplifier is configured to intermittently amplify a third portion of the input signal when the amplifier circuit is operating; and a second impedance inverter connected between an output port from the second peaking amplifier and the combining node.

Some embodiments relate to An amplifier circuit comprising a power splitter; a main amplifier in a first circuit branch coupled to a first port of the power splitter and connected to a combining node with no intervening impedance inverter, wherein the main amplifier is configured to continuously amplify a first portion of an input signal to the amplifier circuit when the amplifier circuit is operating; a first peaking amplifier in a second circuit branch coupled to a second port of the power splitter, wherein the first peaking amplifier is configured to intermittently amplify a second portion of the input signal when the amplifier circuit is operating; and a first impedance inverter connected between an output port from the first peaking amplifier and the combining node.

Some embodiments relate to an amplifier circuit comprising a power splitter; a main amplifier in a first circuit branch coupled to a first port of the power splitter and connected directly to a combining node, wherein the main amplifier is configured to continuously amplify a first portion of an input signal to the amplifier circuit when the amplifier circuit is operating; and a plurality of peaking amplifiers in two or more additional circuit branches coupled to two or more additional ports of the power splitter, wherein the plurality of peaking amplifiers are configured to intermittently amplify plural additional portions of the input signal when the amplifier circuit is operating, wherein the two or more additional circuit branches include impedance inverters connected to the combining node.

Methods of operating a multi-way amplifier are also contemplated. A method embodiment may include acts of receiving an input signal at a power splitter; dividing the input signal into a first signal provided to a first circuit branch, a second signal provided to a second circuit branch, and a third signal provided to a third circuit branch; providing the first signal to a main amplifier and then to a combining node without inverting impedance between the main amplifier and combining node; providing the second signal to a first peaking amplifier in the second circuit branch and a first output signal from the first peaking amplifier to the combining node; and providing the third signal to a second peaking amplifier in the third circuit branch and a second output signal from the second peaking amplifier to the combining node.

The foregoing apparatus and method embodiments may be implemented with any suitable combination of aspects, features, and acts described above or in further detail below. These and other aspects, embodiments, and features of the present teachings can be more fully understood from the following description in conjunction with the accompanying drawings.

### BRIEF DESCRIPTION OF THE DRAWINGS

The skilled artisan will understand that the figures, described herein, are for illustration purposes only. It is to be understood that in some instances various aspects of the embodiments may be shown exaggerated or enlarged to facilitate an understanding of the embodiments. The drawings are not necessarily to scale, emphasis instead being placed upon illustrating the principles of the teachings. In the drawings, like reference characters generally refer to like features, functionally similar and/or structurally similar elements throughout the various figures. Where the drawings relate to microfabricated circuits, only one device and/or circuit may be shown to simplify the drawings. In practice, a large number of devices or circuits may be fabricated in parallel across a large area of a substrate or entire substrate. Additionally, a depicted device or circuit may be integrated within a larger circuit that may not be shown in the drawing in order to simplify the illustration.

When referring to the drawings in the following detailed description, spatial references “top,” “bottom,” “upper,” “lower,” “vertical,” “horizontal,” and the like may be used. Such references are used for teaching purposes, and are not intended as absolute references for embodied devices. An embodied device may be oriented spatially in any suitable manner that may be different from the orientations shown in the drawings. The drawings are not intended to limit the scope of the present teachings in any way.

FIG. 1 depicts a first arrangement of a conventional Doherty amplifier;

FIG. 2 depicts a two-way amplifier having an impedance inverter connected to the output of a peaking amplifier and no impedance inverter connected to the output of the main amplifier, according to some embodiments;

FIG. 3 depicts a three-way amplifier having impedance inverters connected to outputs of two peaking amplifiers, according to some embodiments;

FIG. 4 depicts another example of a three-way amplifier having impedance inverters connected to outputs of two peaking amplifiers;

FIG. 5 depicts a five-way amplifier having impedance inverters connected to outputs of four peaking amplifiers, according to some embodiments;

FIG. 6A illustrates a schematic example of a three-way amplifier circuit, according to some embodiments;

FIG. 6B depicts an example of how a three-way amplifier circuit could be implemented in an amplifier package, according to some embodiments;

FIG. 7 illustrates gain characteristics of a three-way amplifier with impedance inverters connected to outputs of the peaking amplifiers, according to some embodiments; and

FIG. 8 illustrates improvements in efficiency for a three-way amplifier with impedance inverters connected to outputs of the peaking amplifiers, according to some embodiments.

Features and advantages of the illustrated embodiments will become more apparent from the detailed description set forth below when taken in conjunction with the drawings.

### DETAILED DESCRIPTION

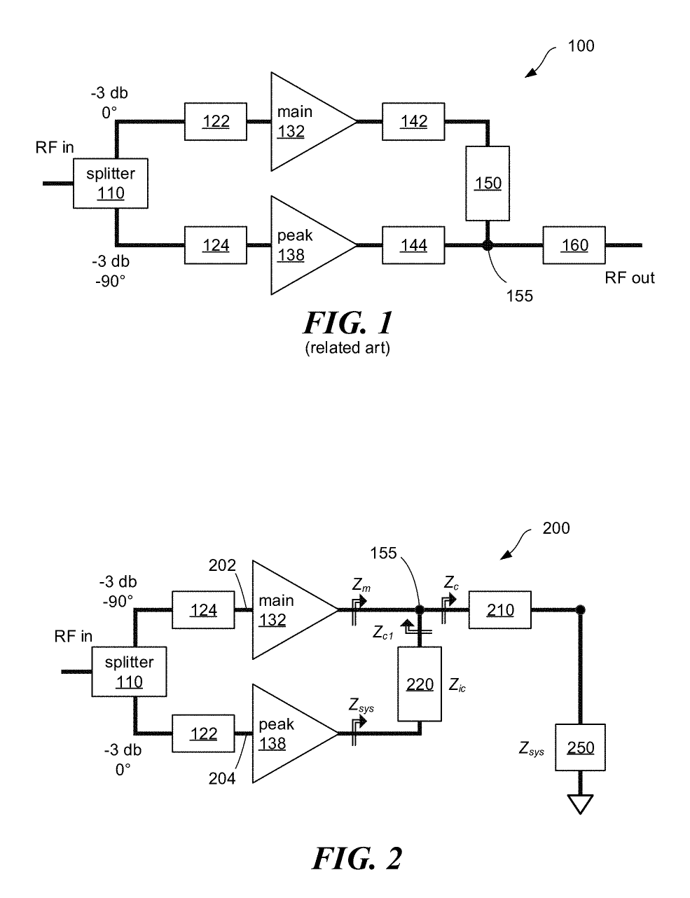

One approach to amplifying signals for communications is to use a Doherty amplifier, an example of which is depicted schematically in FIG. 1. To aid in understanding the present technology, a brief summary of Doherty amplification is provided.

A Doherty amplifier 100 can comprise a 90-degree power splitter 110, which divides a received RF signal into two output signal paths that connect to a main amplifier 132 and a peaking amplifier 138. The main amplifier 132 and peaking amplifier 138 are arranged on parallel circuit branches. The power splitter 110 can also delay (by approximately 90 degrees) the phase of the signal provided to the peaking amplifier with respect to the phase of the signal provided to the main amplifier, as indicated in FIG. 1. Two signals, derived from the RF input signal, can be amplified in parallel by the main amplifier 132 and peaking amplifier 138.

Impedance-matching components 122, 124 can be placed before the main amplifier 132 and peaking amplifier 138. These impedance-matching components may be used to match the impedances of the transmission lines from the 90-degree splitter 110 to the input impedances of the two amplifiers 132, 138, so that signal reflections from the amplifiers are reduced. Additional impedance-matching components 142, 144 can be implemented at the outputs of the main and peaking amplifiers to match impedances between the output of the main amplifier 132 to an input impedance of an inverter 150 (which may be 50 ohms by design) and between the output of the peaking amplifier 138 and a combining node 155. The impedance inverter 150, connected to the output of the main amplifier 132, can rotate the phase of the signal received from the main amplifier 132 so that the signals from the main amplifier and peaking amplifier will be essentially in phase at the combining node 155. As may be appreciated, the impedance inverter 150 compensates for phase delay in the main amplifier circuit branch added by the splitter 110 in the peaking amplifier circuit branch, so that signals recombine in phase at the combining node 155. In embodiments, an output impedance-matching element 160 can connect to the combining node 155 to match the output impedance of the Doherty amplifier to an impedance of a load (not shown) that is driven by the Doherty amplifier.

In overview, the present embodiments relate to improving the performance of multi-way amplifiers. A multi-way amplifier can comprise multiple parallel circuit branches, each containing an amplifier. An input signal can be divided (e.g., via a splitter 110) into two or more signals that are provided to the parallel circuit branches. The signals can be amplified and operated on in each circuit branch before being recombined at a combining node 155. In some implementations, impedance inverters are connected to outputs of peaking amplifiers in a multi-way amplifier configuration. An impedance inverter may not be used at the output of a main amplifier in the multi-way amplifier configuration. The impedance inverters at the outputs of the peaking amplifiers can be engineered to present a desired impedance value to the outputs of the peaking amplifiers when the peaking amplifiers are fully on. A multi-way amplifier circuit of the present embodiments can include two or more parallel circuit branches, and can improve the amplifier's efficiency at 6 dB output power back-off and improve RF bandwidth performance. Bandwidth performance can be improved by better matching of impedances at outputs of the main and peaking amplifiers.

An example configuration of a two-way amplifier circuit 200 is depicted in FIG. 2. A main amplifier 132 and a peaking amplifier 138 can be connected in parallel circuit branches 202, 204 and amplify portions of an input signal that is split by a power divider or signal splitter 110. Signals from outputs of the main amplifier 132 and peaking amplifier 138 can be recombined at a combining node 155. The main amplifier 132 can be configured to continuously amplify its received signal when the amplifier circuit 200 is operating. The peaking amplifier can be configured to intermittently amplify its received signal when the amplifier circuit 200 is operating. For example, the peaking amplifier 138 can be arranged to amplify its received signal only when the input signal to the amplifier circuit (indicated as “RF in”) exceeds a predetermined threshold power. In embodiments, the peaking amplifier 138 may begin amplifying when the main amplifier 132 begins to enter a saturated amplification regime.

The amplifier circuit 200 can be connected to a load 250, which can include real and/or reactive components. Example loads include antennas (e.g., for wireless communication or radar) and signal processing circuitry. In some cases, a load 250 could include a heating device, such as a microwave heater. Other loads 250 can also be driven with the amplifier circuits disclosed herein. Other applications include medical imaging or diagnostic equipment where radio frequency (RF) signals at high power levels (e.g., >20 Watts) are needed.

According to some embodiments, output impedance-matching circuitry 210 (e.g., a matching network and/or a transmission line) can transform a first impedance value Z_{sys} at an input to the load to a lower impedance value at a combining node 155. As an example and without being limited to a particular value, an input impedance Z_{sys} of the load could be essentially 50 ohms, and output impedance-matching circuitry 210 may transform this impedance value to approximately 35 ohms or any other desired value. A lower impedance value at the combining node 155 may provide a better impedance match to an output impedance of the main amplifier 132. In some implementations, the main amplifier 132 can be connected to the combining node 155 via an impedance-matching network (not shown in FIG. 2), which could transform an impedance value at the combining node 155 to an output impedance value of the main amplifier 132.

In embodiments, the peaking amplifier 138 can be connected to the transmission line 210 via an impedance inverter 220. A characteristic impedance Z_{ic} of the impedance inverter 220 can be selected and engineered to obtain a desired impedance value seen by the peaking amplifier 138 when the main amplifier 132 and peaking amplifier 138 are fully amplifying their respective signals. In some cases, it can be desirable to set the impedance value presented to the output of the peaking amplifier 138 to the load impedance Z_{sys}, although other impedance values may be used in other embodiments. Once Z_{sys} or some other value is selected as an impedance presented to the peaking amplifier 138 and the impedance looking into the combining node 155 is determined, the characteristic impedance of the impedance inverter 220 can be calculated from the following expression.

Z_{ic}²=Z_{sys}Z_{c1} (1)

For high off-state alignment of signals from the main amplifier 132 and peaking amplifier 138, short transmission lines with identical impedance seen by the peaking amplifier 138 may be added to the first circuit path to adjust a phase of the signal in that path.

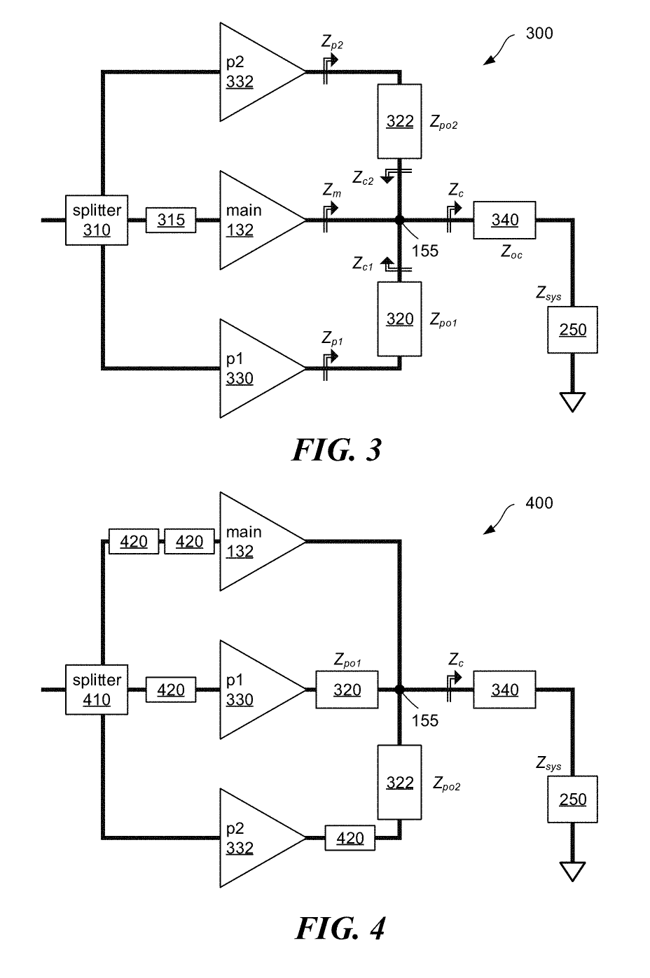

By extension, additional peaking amplifiers can be added and connected to the same combining node 155 to extend the amplifier configuration to a three-way or higher-order multi-way amplifier circuit. FIG. 3 depicts an example of a three-way amplifier circuit 300 that employs a topology in which impedance inverters 320, 322 are connected to the outputs of two peaking amplifiers 330, 332. In this example, the peaking amplifiers are arranged on either side of a main amplifier 132 (e.g., located on opposite sides of a main amplifier 132 on a circuit board). In some embodiments, a three-way amplifier circuit comprises a first peaking amplifier 330 connected to a combining node 155 via a first impedance inverter 320. A characteristic impedance of the first impedance inverter 320 can be Zₚₒ₁. A three-way amplifier circuit 300 can further include a second peaking amplifier 322 that is connected to the combining node 155 via a second impedance inverter 322 having a second characteristic impedance Zₚₒ₂. There can be output impedance-matching circuitry 340 (e.g., an impedance-transforming transmission line or impedance-transforming network) connected to the combining node that transforms an impedance Z_{sys} matched to a load 250 to a lower value of impedance Z_{c}. A characteristic impedance of the output impedance-matching circuitry 340 can be denoted as Z_{oc}.

In embodiments, the impedances Zₚ₁, Zₚ₂ seen by the first and second peaking amplifiers 330, 332 can be selected and engineered (e.g., by designing impedance inverters 320, 322) to have a same impedance, though other values may be used in some cases. As one example, the values of impedances at outputs of the first and second peaking amplifiers 330, 332 can be selected to be Z_{sys}, so that Zₚ₁=Zₚ₂=Z_{sys} when the first and second peaking amplifiers and main amplifier 132 are fully amplifying signals. In some implementations, the first and second peaking amplifiers may handle different amounts of power when fully amplifying. Further, in some cases their power levels may differ from the main amplifier's power level. Different power levels can result in changes to the impedance inverters 320, 322. Techniques for determining the values of characteristic impedances are explained in further detail below.

Alternative three-way amplifier configurations are also possible, and may depend on how a received signal's power is split between the main and peak amplifiers. One alternative configuration of a three-way amplifier circuit 400 is depicted in FIG. 4. According to some embodiments, the second peaking amplifier 332 may be arranged on a circuit board adjacent to the first peaking amplifier 330 rather than on an opposite side of the main amplifier 132.

Phase-delay circuitry 420 (e.g., a transmission line or lumped element network) can provide a phase delay of approximately 180 degrees (other values of phase delay such as 90 degrees may be used in some embodiments), so that a same phase characteristic is obtained in each circuit branch of a multi-way amplifier circuit. Further, phase-delay circuitry 420 can help provide a same impedance at all the peaking amplifiers to maintain a high off-state impedance for the amplifier circuit 400.

Phase-delay circuitry can be added at or after a power splitter 410 in order to provide relative phase delay to the signals transmitted to the main amplifier 132 and peaking amplifiers 330, 332. The added phase delays prior to the main and peaking amplifiers are chosen to properly align the phases of signals at the combining node 155. The input splitter 410 can be of any suitable type including, but not limited to, an RF coupler or Wilkinson splitter.

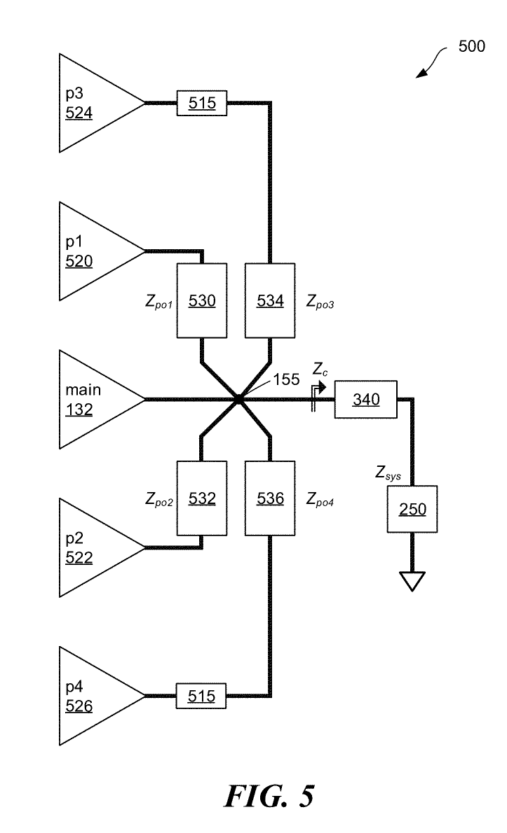

The topology can be extended to higher-order, N-way amplifier circuits. In embodiments, N can be an integer between 2 and 20. An example of a five-way amplifier circuit 500 is depicted in FIG. 5, according to some embodiments. Input circuitry to the main amplifier and peaking amplifiers is not shown to simplify the drawing. The input circuitry can include one or more power splitters, phase-delay elements, and impedance-matching circuitry as indicated in the other multi-way amplifiers of FIG. 2 through FIG. 4. In embodiments, an N-way amplifier circuit 500 can comprise (N−1) peaking amplifiers (four in the illustrated example: 520, 522, 524, 526) having (N−1) impedance inverters (e.g., 530, 532, 534, 536) connected between their output ports and a combining node 155. In some cases, there can be one or more phase-delay elements 515 located in branched circuit paths to and from the peaking amplifiers to align signals for recombination at combining node 155. An N-way amplifier circuit can also comprise a main amplifier 132 having its output port connected to the combining node 155 without an intervening impedance inverter. There can be output impedance-matching circuitry 340 (e.g., an impedance-transforming transmission line or impedance-transforming network) connected to the combining node that transforms an impedance Z_{sys} matched to a load 250 to a lower value of impedance Z_{c}.

Multi-way amplifiers of the present embodiments are capable of amplifying received RF signals to high power levels. In embodiments, a multi-way amplifier may amplify a received signal to power levels between 10 Watts and 40 Watts in each circuit branch. For example, a three-way amplifier can be capable of a total output power between 30 Watts and 120 Watts in some cases, and have an amplifier efficiency greater than 60% at 6 dB output power back-off.

To aid in understanding, and without being bound to a particular theory, various design aspects of an N-way amplifier circuit may be described mathematically. For the case of a three-way amplifier circuit 300 (referring again to FIG. 3), an impedance Zₘ seen by the main amplifier may be described by

Zₘ=Z_{c}(1+m1+m2) (2)

using voltage-current relations at the combining node 155. In this expression, Z_{c} is an impedance transformed from the load or system impedance Z_{sys} due to the output impedance-matching circuitry 340, m1 is a first power ratio (P₁/Pₘ) of the first peaking amplifier 330 power to the main amplifier 132 power, and m2 is a second power ratio (P₂/Pₘ) of the second peaking amplifier 332 power to the main amplifier 132 power.

In embodiments for which the output impedance-matching circuitry 340 is a quarter-wave transmission line with a characteristic impedance Z_{oc}, EQ. 2 can be written as the following equation.

$${Z}_{m} = \frac{{Z}_{oc}^{2}}{{Z}_{sys}} ( 1 + m 1 + m 2 ) \qquad ( 3 )$$

EQ. 3 indicates that the impedance seen by the main amplifier 132 depends in part on the power states of the peaking amplifiers. For example, when both peaking amplifiers are off m1=m2=0 and the impedance seen by the main amplifier becomes the following.

$${Z}_{m} = \frac{{Z}_{oc}^{2}}{{Z}_{sys}} \qquad ( 4 )$$

If only one of the peaking amplifiers is on (e.g., only the first peaking amplifier 330), then the impedance seen by the main amplifier becomes the following.

$${Z}_{m} = \frac{{Z}_{oc}^{2}}{{Z}_{sys}} ( 1 + m 1 ) \qquad ( 5 )$$

According to some embodiments, the impedance Zₚ₁ presented to the first peaking amplifier 330 and the impedance Zₚ₂ presented to the second peaking amplifier are designed to be essentially identical at peak power. For example, the impedances seen at the outputs of the first and second peaking amplifiers 330, 332 can be selected to be equivalent to the load impedance Z_{sys} when the first and second peaking amplifiers are fully on and amplifying. For this selected value, Zₚ₁=Zₚ₂=Z_{sys}. The selection of impedance values presented to the outputs of the peaking amplifiers implies that the characteristic impedances for the impedance inverters 320, 322 should be as follows.

$$\begin{matrix}{Z}_{po 1} = \sqrt{\frac{1 + m 1 x + m 2 x}{m 1 x}} \cdot {Z}_{oc} & ( 6 ) \\ {Z}_{po 2} = \sqrt{\frac{1 + m 1 x + m 2 x}{m 2 x}} \cdot {Z}_{oc} & ( 7 )\end{matrix}$$

In EQ. 6 and EQ. 7, the values for m1x and m2x each represent maximum power ratio values (i.e., the ratio of power of a respective peaking amplifier to the main amplifier when the peaking amplifier is on and fully amplifying at maximum power).

The expressions in EQ. 6 and EQ. 7 provide engineering guidelines for constructing the impedance inverters 320, 322 in a two-way amplifier circuit of the present embodiments. Once an impedance value Z_{sys} is known for a system load and an output impedance is known for a peaking amplifier, an engineer can first construct output impedance-matching circuitry 340 that will transform the load impedance Z_{sys} to a value closer to an output impedance of the main amplifier Zₘ. For example, Z_{sys} may be transformed to a value Z_{c} that is within 30% of the value of Zₘ. Once Z_{c} is determined, Z_{c1} and Z_{c2} can be calculated from fundamental circuit principles. The characteristic impedances of impedance inverters 320, 322 can then be calculated to rotate impedance values Z_{c1} and Z_{c2} back to match desired impedance value Zₚ₁ and Zₚ₂ at the outputs of the peaking amplifiers.

With further analysis, an impedance presented to a peaking amplifier at approximately 6 dB power back-off can be determined from the following expression

$${Z}_{pi} = \frac{{m}_{i} \cdot {Z}_{poi}^{2} \cdot {Z}_{sys}}{{Z}_{oc}^{2} ( 1 + m 1 + m 2 )} \qquad ( 8 )$$

in which i identifies the peaking amplifier (e.g., i=1 or 2 in the three-way amplifier circuit example). The values m1 and m2 may vary between 0 and the respective maximum power ratios m1x, m2x. Higher off-state impedances (e.g., higher than off-state impedances for a conventional Doherty amplifier) for the peaking amplifiers 330, 332 can be obtained for multi-way amplifier circuits of the present embodiments. Higher off-state impedances can reduce signal loss to the peaking amplifiers and improve amplifier efficiency of the amplifier circuits at 6 dB back-off power levels. Efficiencies greater than 60% can be achieved for the multi-way amplifier circuits of the present embodiments.

Analytic processes following the analysis in EQ. 2 through EQ. 8 can be applied to the amplifier circuits illustrated in FIG. 2 and FIG. 5, with appropriate modifications to reflect the number of parallel circuit branches and impedance inverters. Such analyses can be used to determine characteristic impedance values for impedance inverters connected to outputs of peaking amplifiers in multi-way amplifier circuits, and to determine off-state impedances of peaking amplifiers.

There are several improvements relating to the multi-way amplifier circuit configurations described above. In some cases, improved broadband performance can be obtained, because the main amplifier 132 is connected to a combining node 155 at lower impedance that is better matched to the main amplifier, rather than through an impedance inverter as used in conventional Doherty amplifier designs. Higher off-state impedances of the peaking amplifiers can enable higher amplifier higher efficiency at back-off. Additionally, impedance inverters connected to the peaking amplifiers can be readily engineered to provide desired impedances to the outputs of the peaking amplifiers and to adjust for different power ratios among the main amplifier and peaking amplifiers. By adding additional peaking amplifiers, higher power amplifiers can be obtained. In embodiments, a three-way amplifier can amplify signal levels up to approximately 52 dBm before going into compression.

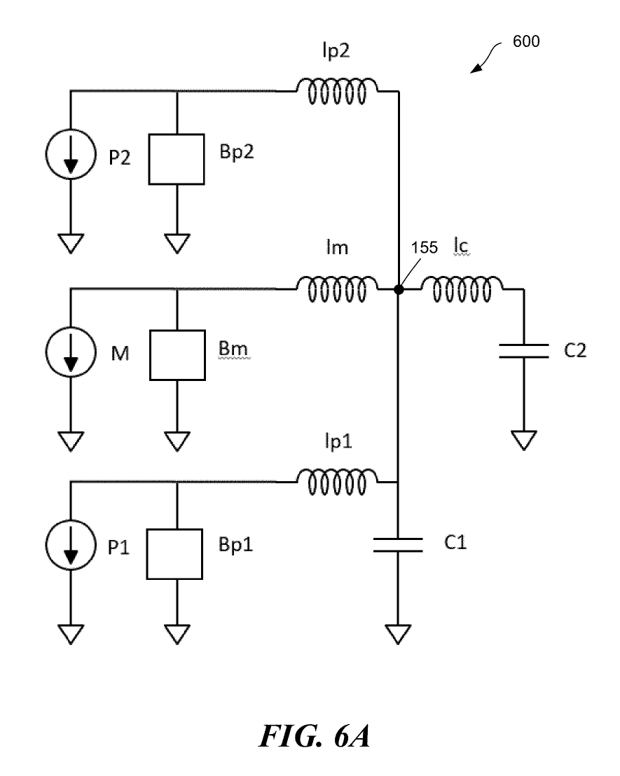

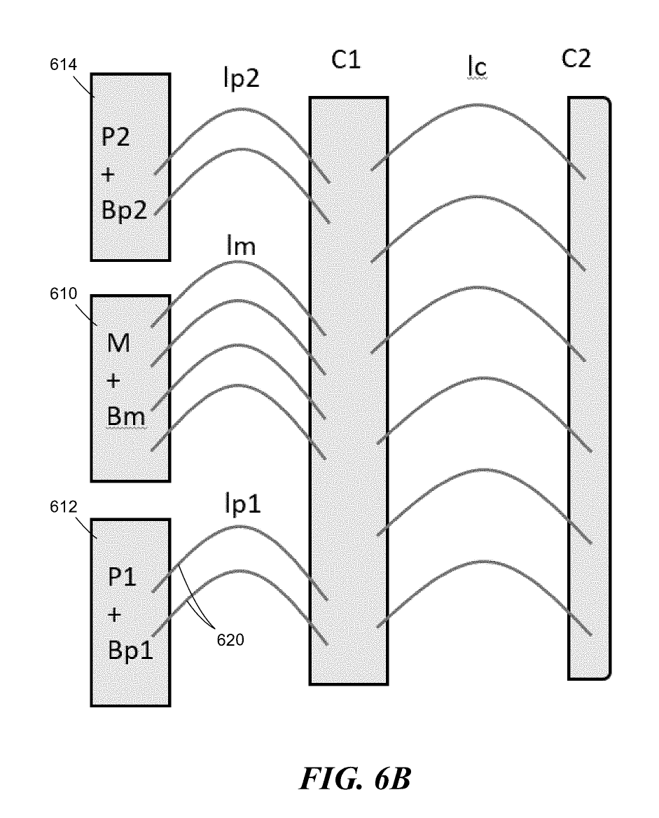

As described above, an impedance inverter connected to the output of a peaking amplifier can be implemented as an integrated transmission line, a lumped element network, or a combination thereof. FIG. 6A and FIG. 6B depict an embodiment in which impedance inverters can be implemented as lumped elements, at least in part. FIG. 6A is a schematic representation of a multi-way peaking amplifier circuit 600 in which the main amplifier M, first peaking amplifier P1, and second peaking amplifier P2 are fully amplifying and represented as current sources. Each of the amplifiers may be connected to LC networks Bm, Bp1, Bp2 at their outputs, which can include output capacitance and output inductance of transistors that are used to make the main and peaking amplifiers. An output of the amplifier circuit 600 can include inductance L_{c} and capacitance C₂, which may have values selected to transform an impedance of a load to a lower impedance value at the combining node 155. Inductance Lₚ₁ and capacitance C₁ can comprise at least part of circuitry for an impedance inverter connected to an output of a first peaking amplifier P1. In some cases, network Bp1 may include components that make up the impedance inverter connected to the output of the first peaking amplifier P1. Inductance Lₚ₂ and capacitance C₁ can comprise at least part of circuitry for an impedance inverter connected to an output of a second peaking amplifier P2. In some cases, network Bp2 may include components that make up the impedance inverter connected to the output of the first peaking amplifier P1.

FIG. 6B illustrates one example in which a multi-way amplifier can be implemented in an amplifier package. According to some implementations, the main amplifier and peaking amplifiers can be implemented as separate dies 610, 612, 614 mounted on an integrated circuit board. Networks Bm, Bp1, Bp2 can comprise integrated circuitry on the respective semiconductor die (e.g., signal traces and bonding pads). Inductances Lₘ, Lₚ₁, Lₚ₂, and L_{c} can comprise bond wires 620, for example. Capacitances C₁ and C₂ can comprise discrete capacitors (e.g., microfabricated bar capacitors).

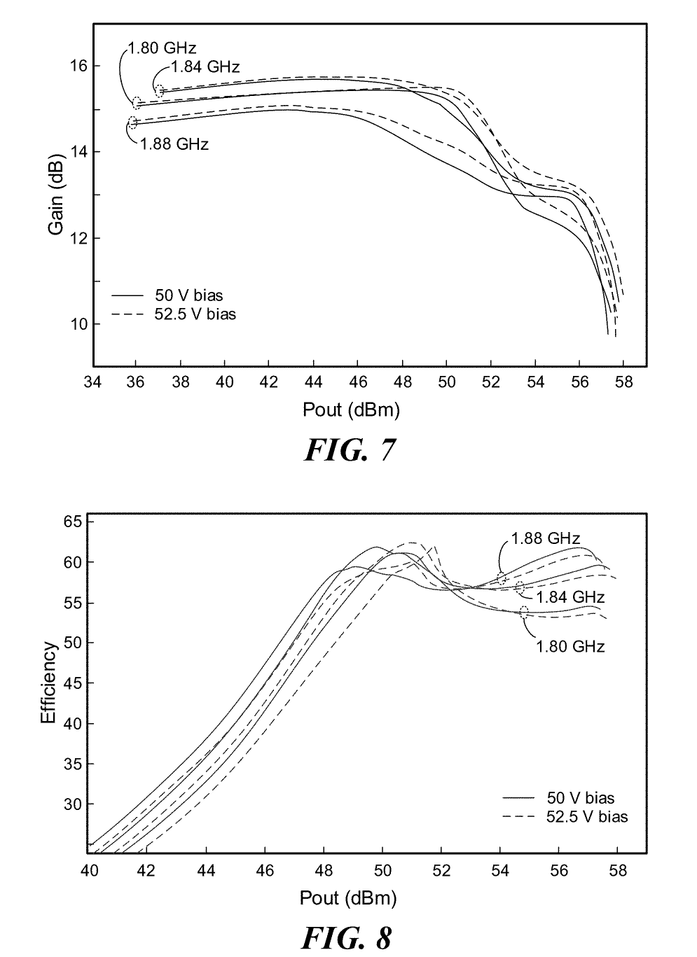

A three-way power amplifier with 1:1:2 power ratios was demonstrated using a star node configuration with impedance inverters connected between peaking amplifiers and a combining node as described above, and no impedance inverter connected between an output of the main amplifier and combining node. The amplifier was assembled on a circuit board and capable of handling 80 W average power. A series of gain-curve measurements were made at different operating frequencies (1.8 GHz, 1.84 GHz, and 1.88 GHz) and different amplifier biasing conditions (50V and 52.5V). The results are plotted in FIG. 7. Additionally, power back-off efficiencies were also measured under the same conditions, and the results are plotted in FIG. 8. The results show that back-off efficiencies between 58% and 64% are possible with output powers of about 50 dBm for the example amplifier. Higher efficiencies may be obtained in other embodiments.

Embodiments of amplifiers of the disclosed technology include the following configurations.

(1) An amplifier circuit comprising:
a power splitter;
a main amplifier in a first circuit branch coupled to a first port of the power splitter and connected directly to a combining node, wherein the main amplifier is configured to continuously amplify a first portion of an input signal to the amplifier circuit when the amplifier circuit is operating;
a first peaking amplifier in a second circuit branch coupled to a second port of the power splitter, wherein the first peaking amplifier is configured to intermittently amplify a second portion of the input signal when the amplifier circuit is operating;
a first impedance inverter connected between an output port from the first peaking amplifier and the combining node;
a second peaking amplifier in a third circuit branch coupled to a third port of the power splitter, wherein the second peaking amplifier is configured to intermittently amplify a third portion of the input signal when the amplifier circuit is operating; and
a second impedance inverter connected between an output port from the second peaking amplifier and the combining node.

(2) The amplifier circuit of configuration (1), wherein the first impedance inverter transforms an impedance value seen at its output to a first impedance value at its input seen by the first peaking amplifier when the main amplifier, first peaking amplifier, and second peaking amplifier are fully on, and wherein the first impedance value is essentially equivalent to an impedance of a specified load for the amplifier circuit.

(3) The amplifier circuit of configuration (2), further comprising output impedance-matching circuitry connected between the combining node and an output of the amplifier circuit, wherein a characteristic impedance of the first impedance inverter is proportional to a characteristic impedance of the output impedance-matching circuitry.

(4) The amplifier circuit of configuration (3), wherein a characteristic impedance of the first impedance inverter is further inversely proportional to (m1)^{1/2}, where m1 is a ratio of amplified power from the first peaking amplifier to amplified power from the main amplifier when the first peaking amplifier is fully amplifying.

(5) The amplifier circuit of configuration (3) or (4), wherein the output impedance-matching circuitry transforms a load impedance at an output of the amplifier circuit to a lower impedance value at an input to the output impedance-matching circuitry.

(6) The amplifier circuit of any one of configurations (1) through (5), wherein the second impedance inverter transforms an impedance value seen at its output to a second impedance value at its input seen by the second peaking amplifier, wherein the second impedance value is essentially equivalent to an impedance of a specified load for the amplifier circuit.

(7) The amplifier circuit of configuration (6), wherein a characteristic impedance of the second impedance inverter is inversely proportional to (m2)^{1/2}, where m2 is a ratio of amplified power from the second peaking amplifier to amplified power from the main amplifier when the second peaking amplifier is fully amplifying.

(8) The amplifier circuit of any one of configurations (1) through (7), the first peaking amplifier and the second peaking amplifier are located on opposite sides of the main amplifier.

(9) The amplifier circuit of any one of configurations (1) through (8), wherein a first amount of power handled by the first peaking amplifier is different from a second amount of power handled by the second peaking amplifier when the first peaking amplifier and second peaking amplifier are fully amplifying.

(10) The amplifier circuit of any one of configurations (1) through (9), wherein an efficiency of the amplifier at 6 dB back-off is between 58% and 64%.

(11) The amplifier circuit of any one of configurations (1) through (10), further comprising output impedance-matching circuitry that transforms a load impedance at an output of the output impedance-matching circuitry to a lower impedance value at an input of the output impedance-matching circuitry.

(12) The amplifier circuit of any one of configurations (1) through (11), wherein one or both of the first impedance inverter and second impedance inverter comprises an integrated transmission line.

(13) The amplifier circuit of any one of configurations (1) through (12), wherein at least one of the main amplifier, first peaking amplifier, and second peaking amplifier comprises a gallium-nitride transistor.

Embodiments include the following methods of operating a multi-way amplifier. The multi-way amplifier may be an amplifier as described in configurations (1)-(13), (21) or (22).

(14) A method of operating an amplifier circuit, the method comprising receiving an input signal at a power splitter; dividing the input signal into a first signal provided to a first circuit branch, a second signal provided to a second circuit branch, and a third signal provided to a third circuit branch; providing the first signal to a main amplifier and then to a combining node without inverting impedance between the main amplifier and combining node; providing the second signal to a first peaking amplifier in the second circuit branch and a first output signal from the first peaking amplifier to the combining node; and providing the third signal to a second peaking amplifier in the third circuit branch and a second output signal from the second peaking amplifier to the combining node.

(15) The method of (14), further comprising providing the first output signal from the first peaking amplifier to a first impedance inverter and then to the combining node; and providing the second output signal from the second peaking amplifier to a second impedance inverter and then to the combining node.

(16) The method of (15), further comprising amplifying, with the amplifier circuit, the input signal with an amplifier efficiency at 6 dB back-off between 58% and 64%.

(17) The method of (15) or (16), further comprising transforming, by the first impedance inverter, an impedance value at the combining node to a value at an input of the first impedance inverter that is essentially equivalent to an impedance of a specified load for the amplifier circuit.

(18) The method of (16) or (17), further comprising transforming, by the second impedance inverter, an impedance value at the combining node to a value at an input of the second impedance inverter that is essentially equivalent to an impedance of a specified load for the amplifier circuit.

(19) The method of (18), wherein a first amount of power handled by the first peaking amplifier is different from a second amount of power handled by the second peaking amplifier when the first peaking amplifier and second peaking amplifier are fully amplifying.

(20) The method of any one of (14) through (19), further comprising transforming, with output impedance-matching circuitry, a load impedance at an output of the amplifier circuit to a lower impedance value at an input to the output impedance-matching circuitry.

Embodiments also include the following configuration, which can be combined with aspects in configurations (2) through (13).

(21) An amplifier circuit comprising a power splitter; a main amplifier in a first circuit branch coupled to a first port of the power splitter and connected to a combining node with no intervening impedance inverter, wherein the main amplifier is configured to continuously amplify a first portion of an input signal to the amplifier circuit when the amplifier circuit is operating; a first peaking amplifier in a second circuit branch coupled to a second port of the power splitter, wherein the first peaking amplifier is configured to intermittently amplify a second portion of the input signal when the amplifier circuit is operating; and a first impedance inverter connected between an output port from the first peaking amplifier and the combining node.

Embodiments also include the following configuration, which can be combined with aspects in configurations (2) through (13).

(22) An amplifier circuit comprising a power splitter; a main amplifier in a first circuit branch coupled to a first port of the power splitter and connected directly to a combining node, wherein the main amplifier is configured to continuously amplify a first portion of an input signal to the amplifier circuit when the amplifier circuit is operating; and a plurality of peaking amplifiers in two or more additional circuit branches coupled to two or more additional ports of the power splitter, wherein the plurality of peaking amplifiers are configured to intermittently amplify plural additional portions of the input signal when the amplifier circuit is operating, wherein the two or more additional circuit branches include impedance inverters connected to the combining node.

### CONCLUSION

The terms “approximately” and “about” may be used to mean within ±20% of a target dimension in some embodiments, within ±10% of a target dimension in some embodiments, within ±5% of a target dimension in some embodiments, and yet within ±2% of a target dimension in some embodiments. The terms “approximately” and “about” may include the target dimension. The term “essentially” may be used to mean within ±3% of a target dimension.

The technology described herein may be embodied as a method, of which at least some acts have been described. The acts performed as part of the method may be ordered in any suitable way. Accordingly, embodiments may be constructed in which acts are performed in an order different than described, which may include performing some acts simultaneously, even though described as sequential acts in illustrative embodiments. Additionally, a method may include more acts than those described, in some embodiments, and fewer acts than those described in other embodiments.

Having thus described at least one illustrative embodiment of the invention, various alterations, modifications, and improvements will readily occur to those skilled in the art. Such alterations, modifications, and improvements are intended to be within the spirit and scope of the invention. Accordingly, the foregoing description is by way of example only and is not intended as limiting. The invention is limited only as defined in the following claims and the equivalents thereto.

What is claimed is:

1. An amplifier circuit comprising:
a power splitter;
a main amplifier in a first circuit branch coupled to a first port of the power splitter and connected directly to a combining node, wherein the main amplifier is configured to continuously amplify a first portion of an input signal to the amplifier circuit when the amplifier circuit is operating;
a first peaking amplifier in a second circuit branch coupled to a second port of the power splitter, wherein the first peaking amplifier is configured to intermittently amplify a second portion of the input signal when the amplifier circuit is operating;
a first impedance inverter connected between an output port from the first peaking amplifier and the combining node;
a second peaking amplifier in a third circuit branch coupled to a third port of the power splitter, wherein the second peaking amplifier is configured to intermittently amplify a third portion of the input signal when the amplifier circuit is operating; and
a second impedance inverter connected between an output port from the second peaking amplifier and the combining node.

2. The amplifier circuit of claim 1, wherein the first impedance inverter transforms an impedance value seen at its output to a first impedance value at its input seen by the first peaking amplifier when the main amplifier, first peaking amplifier, and second peaking amplifier are fully on, and wherein the first impedance value is essentially equivalent to an impedance of a specified load for the amplifier circuit.

3. The amplifier circuit of claim 2, further comprising output impedance-matching circuitry connected between the combining node and an output of the amplifier circuit, wherein a characteristic impedance of the first impedance inverter is proportional to a characteristic impedance of the output impedance-matching circuitry.

4. The amplifier circuit of claim 3, wherein a characteristic impedance of the first impedance inverter is further inversely proportional to (m₁)^{1/2}, where m₁ is a ratio of amplified power from the first peaking amplifier to amplified power from the main amplifier when the first peaking amplifier is fully amplifying.

5. The amplifier circuit of claim 3, wherein the output impedance-matching circuitry transforms a load impedance at an output of the amplifier circuit to a lower impedance value at an input to the output impedance-matching circuitry.

6. The amplifier circuit of claim 1, wherein the second impedance inverter transforms an impedance value seen at its output to a second impedance value at its input seen by the second peaking amplifier, wherein the second impedance value is essentially equivalent to an impedance of a specified load for the amplifier circuit.

7. The amplifier circuit of claim 6, wherein a characteristic impedance of the second impedance inverter is inversely proportional to (m₂)^{1/2}, where m₂ is a ratio of amplified power from the second peaking amplifier to amplified power from the main amplifier when the second peaking amplifier is fully amplifying.

8. The amplifier circuit of any one of claims 1 through 7, the first peaking amplifier and the second peaking amplifier are located on opposite sides of the main amplifier.

9. The amplifier circuit of any one of claims 1 through 8, wherein a first amount of power handled by the first peaking amplifier is different from a second amount of power handled by the second peaking amplifier when the first peaking amplifier and second peaking amplifier are fully amplifying.

10. The amplifier circuit of any one of claims 1 through 9, wherein an efficiency of the amplifier at 6 dB back-off is between 58% and 64%.

11. The amplifier circuit of any one of claims 1 through 10, further comprising output impedance-matching circuitry that transforms a load impedance at an output of the output impedance-matching circuitry to a lower impedance value at an input of the output impedance-matching circuitry.

12. The amplifier circuit of any one of claims 1 through 11, wherein one or both of the first impedance inverter and second impedance inverter comprises an integrated transmission line.

13. The amplifier circuit of any one of claims 1 through 12, wherein at least one of the main amplifier, first peaking amplifier, and second peaking amplifier comprises a gallium-nitride transistor.

14. A method of operating an amplifier circuit, the method comprising:
receiving an input signal at a power splitter;
dividing the input signal into a first signal provided to a first circuit branch, a second signal provided to a second circuit branch, and a third signal provided to a third circuit branch;
providing the first signal to a main amplifier and then to a combining node without inverting impedance between the main amplifier and combining node;
providing the second signal to a first peaking amplifier in the second circuit branch and a first output signal from the first peaking amplifier to the combining node; and
providing the third signal to a second peaking amplifier in the third circuit branch and a second output signal from the second peaking amplifier to the combining node.

15. The method of claim 14, further comprising:
providing the first output signal from the first peaking amplifier to a first impedance inverter and then to the combining node; and
providing the second output signal from the second peaking amplifier to a second impedance inverter and then to the combining node.

16. The method of claim 15, further comprising amplifying, with the amplifier circuit, the input signal with an amplifier efficiency at 6 dB back-off between 58% and 64%.

17. The method of claim 15 or 16, further comprising transforming, by the first impedance inverter, an impedance value at the combining node to a value at an input of the first impedance inverter that is essentially equivalent to an impedance of a specified load for the amplifier circuit.

18. The method of claim 16, further comprising transforming, by the second impedance inverter, an impedance value at the combining node to a value at an input of the second impedance inverter that is essentially equivalent to an impedance of a specified load for the amplifier circuit.

19. The method of claim 18, wherein a first amount of power handled by the first peaking amplifier is different from a second amount of power handled by the second peaking amplifier when the first peaking amplifier and second peaking amplifier are fully amplifying.

20. The method of any one of claims 14 through 19, further comprising transforming, with output impedance-matching circuitry, a load impedance at an output of the amplifier circuit to a lower impedance value at an input to the output impedance-matching circuitry.

21. An amplifier circuit comprising:
a power splitter;
a main amplifier in a first circuit branch coupled to a first port of the power splitter and connected to a combining node with no intervening impedance inverter, wherein the main amplifier is configured to continuously amplify a first portion of an input signal to the amplifier circuit when the amplifier circuit is operating;
a first peaking amplifier in a second circuit branch coupled to a second port of the power splitter, wherein the first peaking amplifier is configured to intermittently amplify a second portion of the input signal when the amplifier circuit is operating; and
a first impedance inverter connected between an output port from the first peaking amplifier and the combining node.

22. An amplifier circuit comprising:
a power splitter;
a main amplifier in a first circuit branch coupled to a first port of the power splitter and connected directly to a combining node, wherein the main amplifier is configured to continuously amplify a first portion of an input signal to the amplifier circuit when the amplifier circuit is operating; and
a plurality of peaking amplifiers in two or more additional circuit branches coupled to two or more additional ports of the power splitter, wherein the plurality of peaking amplifiers are configured to intermittently amplify plural additional portions of the input signal when the amplifier circuit is operating, wherein the two or more additional circuit branches include impedance inverters connected to the combining node.
